(19) United States
(12) Patent Application Publication
(10) Pub. No.: US 2012/0146094 A1
(43) Pub. Date: Jun. 14, 2012

(54) NITRIDE BASED SEMICONDUCTOR DEVICE

(75) Inventors: Younghwan PARK, Seoul (KR); Kiyeol Park, Gyeonggi-do (KR); Woochul Jeon, Gyeonggi-do (KR)

(73) Assignee: SAMSUNG ELECTRO-MECHANICS CO., LTD.

(21) Appl. No.: 13/048,535

(22) Filed: Mar. 15, 2011

(30) Foreign Application Priority Data
Dec. 9, 2010 (KR) 10-2010-0125286

(51) Int. Cl. H01L 29/778

(52) U.S. Cl. 257/194; 257/E29.246

(57) ABSTRACT

Disclosed herein is a nitride based semiconductor device. There is provided a nitride based semiconductor device including: a base substrate; a semiconductor layer disposed on the base substrate; and an electrode structure disposed on the semiconductor layer, wherein the electrode structure includes: a cathode structure ohmic-contacting the semiconductor layer; and an anode structure having a schottky electrode schottky-contacting the semiconductor layer and an ohmic electrode ohmic-contacting the nitride layer.

### CROSS REFERENCE(S) TO RELATED APPLICATIONS

This application claims the benefit under 35 U.S.C. Section 119 of Korean Patent Application Serial No. 10-2010-0125286, entitled “Nitride Based Semiconductor Device” filed on Dec. 9, 2010, which is hereby incorporated by reference in its entirety into this application.

### BACKGROUND OF THE INVENTION

1. Technical Field

The present invention relates to a nitride based semiconductor device, and more particularly, to a nitride based semiconductor device capable of performing a forward operation at a low turn-on voltage and increasing withstand voltage at the time of a reverse operation.

2. Description of the Related Art

A schottky diode among semiconductor devices is a device using a schottky contact that is a junction of a metal and a semiconductor. As the schottky diodes, there is a nitride based semiconductor device using 2-dimensional electron gas (2DEG) as a current moving channel. The nitride based semiconductor device has a base substrate such as a sapphire substrate, an epitaxial growth layer formed on the base substrate, and a schottky electrode and an ohmic electrode formed on the epitaxial growth layer. Generally, the schottky electrode is used as an anode and the ohmic electrode is used as a cathode.

However, the nitride based semiconductor schottky diode having the above structure has a trade-off relation between satisfying low turn-on voltage and low turn-off current and increasing withstand voltage at the time of a reverse operation. Therefore, it is very difficult to implement a technical of lowering a forward turn-on voltage while increasing the withstand voltage at the time of the reverse operation in a general nitride based semiconductor device.

### SUMMARY OF THE INVENTION

An object of the present invention is to provide a nitride based semiconductor device capable of being operated at low turn-on voltage.

Another object of the present invention is to provide a nitride based semiconductor device capable of increasing withstand voltage at the time of a reverse operation.

According to an exemplary embodiment of the present invention, there is provided a nitride based semiconductor device, including: a base substrate; a semiconductor layer disposed on the base substrate and generating 2-dimensional electron (2DEG) therein; and an electrode structure disposed on the semiconductor layer, wherein the electrode structure includes: a first ohmic electrode ohmic-contacting the semiconductor layer; a second ohmic electrode ohmic-contacting the semiconductor layer and spaced apart from the first ohmic electrode; and a schottky electrode unit schottky-contacting the semiconductor layer and disposed to be adjacent to the second ohmic electrode while exposing the side of the second ohmic electrode opposite to the first ohmic electrode.

The side of the second ohmic electrode opposite to the first ohmic electrode may form a coplanar with the side of the schottky electrode unit.

The schottky electrode unit may cover the second ohmic electrode to selectively expose only the side of the second ohmic electrode opposite to the first ohmic electrode.

The second ohmic electrode may be provided in plural, and the second ohmic electrodes may be disposed in a line along a direction parallel with the side of the first ohmic electrode opposite to the schottky electrode unit.

The second ohmic electrode may be provided in plural, and each of the second ohmic electrodes may have an island-shaped transverse section.

The schottky electrode unit may be formed so that the side thereof opposite to the first ohmic electrode has a rugged structure, and the second ohmic electrode may have a structure in which it is inserted into the concave portion of the rugged structure.

According to another exemplary embodiment of the present invention, there is provided a nitride based semiconductor device, including: a base substrate; a semiconductor layer disposed on the base substrate; and an electrode structure disposed on the semiconductor layer, wherein the electrode structure includes: a cathode structure ohmic-contacting the semiconductor layer; and an anode structure having a schottky electrode schottky-contacting the semiconductor layer and an ohmic electrode ohmic-contacting the nitride layer, wherein the schottky electrode is disposed to be adjacent to the ohmic electrode while exposing the side of the ohmic electrode opposite to the cathode structure.

The ohmic electrode may lower the turn-on voltage of the anode structure.

The side of the schottky electrode opposite to the cathode structure may form a coplanar with the side of the ohmic electrode.

The ohmic electrode may be covered with the schottky electrode.

The ohmic electrode may be provided in plural, and the ohmic electrodes may be disposed in a line, being spaced by a predetermined interval according to the schottky electrode.

The schottky electrode may be disposed to be adjacent to the ohmic electrode at the side portion of the ohmic electrode.

The schottky electrode may be disposed in the central area of the semiconductor layer, the cathode structure may be disposed to surround the schottky electrode, and the ohmic electrodes may be disposed to be spaced by a predetermined interval along the edge area of the schottky electrode.

The schottky electrode may be formed so that the side thereof opposite to the cathode structure has a rugged structure, and the ohmic electrode may have a structure in which it is inserted into the concave portion of the rugged structure.

The base substrate may be at least any one of a silicon substrate, a silicon carbide substrate, and a sapphire substrate.

The semiconductor layer may include: a lower nitride layer using the base substrate as a seed layer and grown on the base substrate; and an upper nitride layer formed on the lower nitride layer using the lower nitride layer as the seed layer and having a wider energy band gap than the lower nitride layer, wherein 2-dimensional electron gas (2DEG) is generated between the lower nitride layer and the upper nitride layer.

### BRIEF DESCRIPTION OF THE DRAWINGS

FIG. 1 is a plan view showing a nitride based semiconductor device according to an exemplary embodiment of the present invention;

FIG. 2 is a cross-sectional view taken along line I-I′ of FIG. 1;

FIG. 3 is a cross-sectional view taken along line II-II′ of FIG. 1;

FIGS. 4A to 4D are diagrams for explaining a detailed operational process of a nitride based semiconductor device according to an exemplary embodiment of the present invention.

FIG. 5 is a plan view showing a modified example of a nitride based semiconductor device according to the exemplary embodiment of the present invention;

FIG. 6 is a cross-sectional view taken along line of FIG. 5;

FIG. 7 is a plan view showing another modified example of a nitride based semiconductor device according to the exemplary embodiment of the present invention; and

FIG. 8 is a cross-sectional view taken along line IV-IV′ of FIG. 7.

### DESCRIPTION OF THE PREFERRED EMBODIMENTS

Various advantages and features of the present invention and methods for accomplishing them will become apparent from the following description of embodiments with reference to the accompanying drawings. However, the present invention may be modified in many different forms and it should not be limited to the embodiments set forth herein. These embodiments may be provided so that this disclosure will be thorough and complete, and will fully convey the scope of the invention to those skilled in the art. Like reference numerals throughout the present specification denote like elements.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

Hereinafter, a semiconductor device and a method for manufacturing the same according to exemplary embodiments of the present invention will be described with reference to the accompanying drawings.

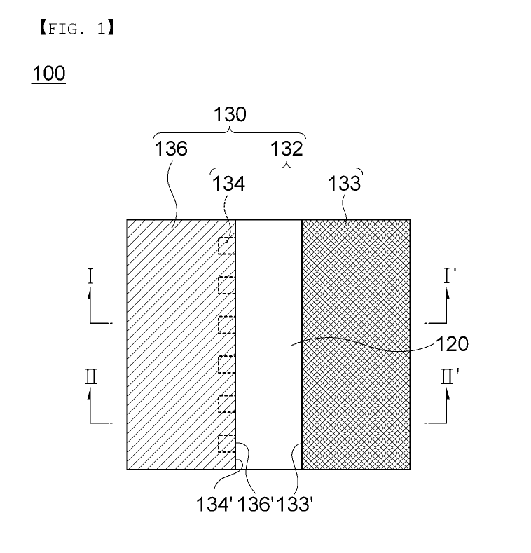

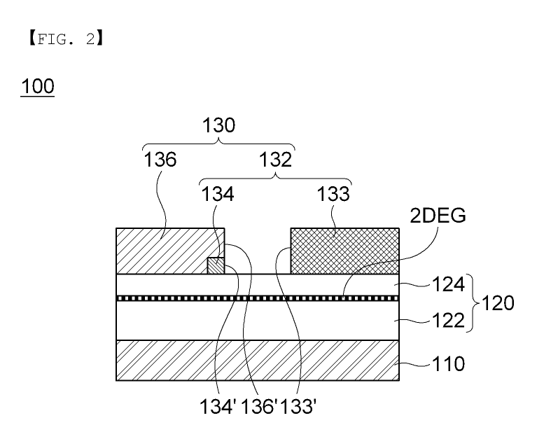

FIG. 1 is a plan view showing a nitride based semiconductor device according to an exemplary embodiment of the present invention and FIG. 2 is a cross-sectional view taken along line I-I′ of FIG. 1. FIG. 3 is a cross-sectional view taken along line II-II′ of FIG. 1.

Referring to FIGS. 1 to 3, a nitride based semiconductor device 100 according to an embodiment of the present invention may be configured to include a base substrate 110, a semiconductor layer 120, and an electrode structure 130.

The base substrate 110 may be a base for forming the semiconductor layer 120 and the electrode structure 130. As the base substrate 110, various kinds of substrates may be used. For example, as the base substrate 110, any one of a silicon substrate, a silicon carbide substrate, and a sapphire substrate may be used.

The semiconductor layer 120 may be a layer composed of a predetermined semiconductor formed on the base substrate 110. For example, the semiconductor layer 120 may be a nitride layer formed by being subjected to an epitaxial growth process using the base substrate 110 as a seed layer. The semiconductor layer 120 may be configured to include a lower nitride layer 122 and an upper nitride layer 124 that are sequentially stacked on the base substrate 110. The upper nitride layer 124 may be made of a material having a wider energy band gap than that of the lower nitride layer 122. In addition, the upper nitride layer 124 may be made of a material having a lattice parameter different from that of the lower nitride layer 122.

For example, the lower nitride layer 122 and the upper nitride layer 124 may be layers including III-nitride based materials. In more detail, the lower nitride layer 122 may be made of any one of gallium nitride (GaN), aluminum gallium nitride (AlGaN), indium gallium nitride (InGaN), and indium aluminum gallium nitride (InAlGaN), and the upper nitride layer 124 may be made of the other one of gallium nitride (GaN), aluminum gallium nitride (AlGaN), indium gallium nitride (InGaN), and indium aluminum gallium nitride (InAlGaN). As an example, the lower nitride layer 122 may be a gallium nitride (GaN) layer, and the upper nitride layer 124 may be an aluminum gallium nitride (AlGaN) layer.

In the semiconductor layer 120, the second-dimensional electron gas (2DEG) may be generated at a boundary between the lower nitride layer 122 and the upper nitride layer 124. At the time of the switching operation of the nitride based semiconductor device 100, current may flow through the second-dimensional electron gas (2DEG).

A buffer layer (not shown) may be interposed between the base substrate 110 and the semiconductor layer 120. The buffer layer may be a layer to reduce the occurrence of defects due to a lattice mismatch between the base substrate 110 and the semiconductor layer 120. To this end, the buffer layer may have a super-lattice layer structure in which thin films made of heterogeneous materials are alternately stacked. The super-lattice layer may have a multi-layer structure in which an insulator layer and a semiconductor layer are alternately grown.

The electrode structure 130 may be disposed on the semiconductor layer 120. The electrode structure 130 may have an ohmic electrode unit 132 and a schottky electrode unit 136. The ohmic electrode unit 132 ohmic-contacts with the semiconductor layer 120 and the schottky electrode unit 136 may be a metal layer schottky contacting the semiconductor layer 120.

The ohmic electrode unit 132 may be configured to include a first ohmic electrode 133 and a second ohmic electrode 134. The first ohmic electrode 133 may be disposed at one area of the semiconductor layer 120. The first ohmic electrode 133 may have a plate shape. The second ohmic electrode 134 may be disposed in the other area of the semiconductor layer 120 while being spaced apart from the first ohmic electrode 133.

The second ohmic electrode 134 may be provided in plural. When the second ohmic electrode 134 is provided in plural, the second ohmic electrodes 134 may be disposed in a line to be spaced by a predetermined interval along a direction parallel with the first side 133′. Each of the second ohmic electrode 134 may have an island-shaped transverse section. As an example, the transverse section of the second ohmic electrodes 134 may have a polygonal shape such as a triangular shape and a quadrangular shape or a polygonal shape of a modified shape having a partially curved shape.

In this case, the side of the first ohmic electrode 133 (hereinafter, ‘first side 133’) opposite to the second ohmic electrode 134 and the side (hereinafter, a second side 134′) of the second ohmic electrode 134 opposite to the first ohmic electrode 133 may be provided to be parallel with each other. The first ohmic electrode 133 may be used as the cathode structure of the nitride based semiconductor device 100.

A portion of the schottky electrode unit 136 may be configured to cover the first ohmic electrode 133 in the other area of the semiconductor layer 120. For example, the schottky electrode unit 136 may have the side (hereinafter, referred to as ‘a third side 136’) opposite to the first ohmic electrode 133. The third side 136′ may have a rugged structure having a concaved portion and a convex portion toward the first ohmic electrode 133. In addition, the schottky electrode unit 136 may be provided so that the third side 136′ forms a coplanar with the second side 134′. To this end, the second ohmic electrode 134 may have a structure in which it is laterally inserted into the concave part of the rugged structure. Therefore, the second side 134′ of the second ohmic electrode 134 and the third side 136′ of the schottky electrode unit 136 forms a coplanar, which may be opposite to the first side 133′ of the first ohmic electrode 133. The schottky electrode unit 136 may be used as the anode structure of the device 100, together with the second ohmic electrode 134.

The electrode structure 130 having the above-mentioned structure may have the anode structure in which the plurality of second ohmic electrodes 134 are provided in the schottky electrode unit 136. The turn-on voltage of the schottky electrode unit 136 may be lowered by the second ohmic electrodes 134. In more detail, the turn-on voltage of the schottky contact of the anode structure may be substantially lowered to 0 by the second ohmic electrodes 134 forming the ohmic contact with the semiconductor layer 120. Therefore, the turn-on voltage at the time of the forward operation of the device 100, such that the device 100 may be operated even at the low turn-on voltage.

Next, a detailed operation process of a nitride based semiconductor device according to an exemplary embodiment of the present invention will be described in detail. In this configuration, the overlapped description of the nitride based semiconductor device 100 described with reference to FIGS. 1 and 3 may be omitted or simplified.

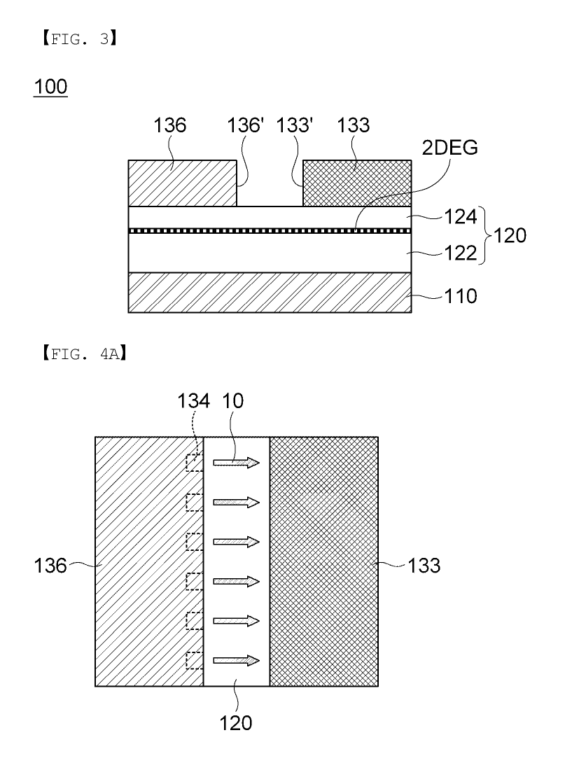

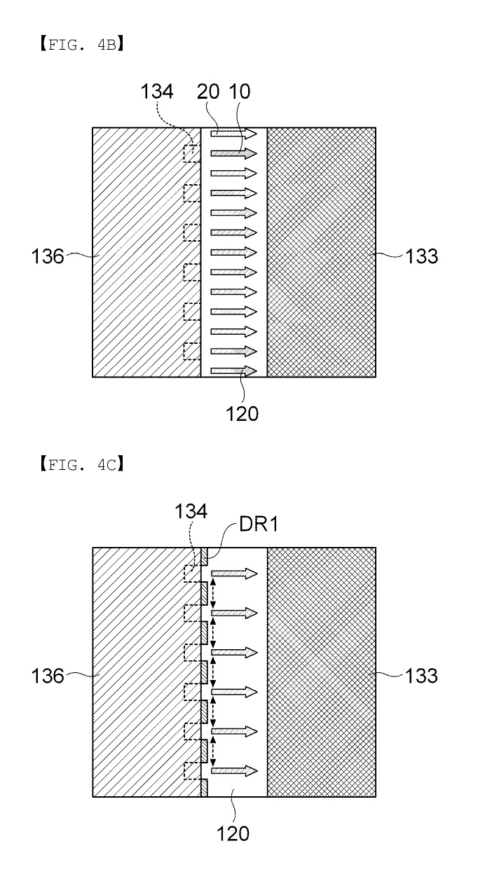

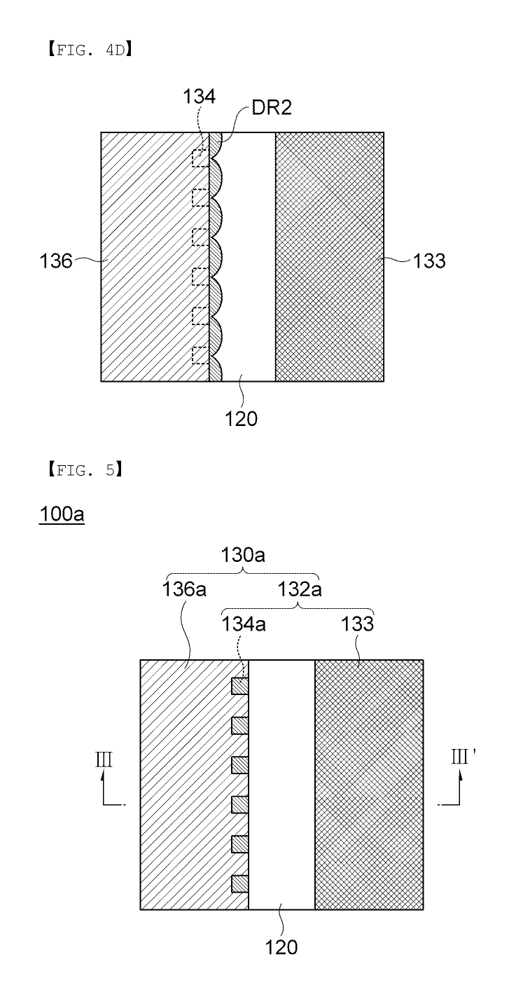

FIGS. 4A to 4D are diagrams for explaining a detailed operational process of a nitride based semiconductor device according to an exemplary embodiment of the present invention. In more detail, FIG. 4A is a diagram showing a current flow when a lower voltage than the turn-on voltage of the schottky electrode is applied, when the nitride based semiconductor device according to the exemplary embodiment of the present invention is driven forward. FIG. 4B is a diagram showing a current flow when a higher voltage than the turn-on voltage of the schottky electrode is applied to the nitride based semiconductor device, when the nitride based semiconductor device according to the exemplary embodiment of the present invention is driven forward. FIGS. 4C and 4D are drawing for explaining a process of blocking a current flow through the 2-D electron gas by the depletion area of the schottky area by applying a reverse driving voltage to the nitride semiconductor device according to the exemplary embodiment of the present invention.

Referring to FIG. 4A, when the nitride based semiconductor device according to the exemplary embodiment of the present invention is driven forward at lower voltage than the turn-on voltage of the schottky electrode unit 136, the current flow may be selectively flow only through the ohmic contact of the second ohmic electrode 134. That is, when the nitride based semiconductor voltage is driven forward at a lower voltage than the turn-on voltage of the schottky contact of the schottky electrode unit 136, the current flow through the schottky electrode unit 136 may be not generated and only the current 10 through the second ohmic electrode 134 may selectively flow.

Referring to FIG. 4B, when the nitride based semiconductor device according to the exemplary embodiment of the present invention is driven forward at the higher voltage than the turn-on voltage of the schottky electrode unit 136, the current flow may include a current 20 through the schottky contact of the schottky electrode unit 136, together with the current 10 through the ohmic contact of the second ohmic electrode 134. That is, when the nitride based semiconductor device according to the exemplary embodiment of the present invention is driven forward at a higher voltage than the turn-on voltage of the schottky contact of the schottky electrode unit 136, the current 10 and 20 may flow through the second ohmic electrode 134 and the schottky electrode unit 136.

Referring to FIG. 4C, when the nitride based semiconductor device according to the exemplary embodiment of the present invention starts to be applied with a reverse voltage at the time of being driven reversely, the flow of current 10 through the second ohmic electrode 134 may be blocked by a depletion region (DR1) caused by the schottky contact of the schottky electrode unit 136. Further, when the magnitude in reverse voltage is increased, as shown in FIG. 4D, the flow of current 20 through other schottky electrode unit 136 may be blocked by an expanded depletion region (DR2).

As described above, the nitride based semiconductor device 100 according to the exemplary embodiment of the present invention is configured to include the semiconductor layer 120 formed on the base substrate 110 and the electrode structure 130 formed on the semiconductor layer 120, wherein the electrode structure 130 may have a structure where the second ohmic electrodes 134 ohmic contacting the semiconductor layer 120 are inserted into the schottky electrode unit 136 used as the anode. In this case, the current 10 is generated through the second ohmic electrodes 134 at the lower voltage than the schottky contact of the schottky electrode unit 136 and the current 20 may be generated through the schottky electrode unit 136, together with the current 10 through the second ohmic electrodes 134 at the higher turn-on voltage than that of the schottky contact. Therefore, the nitride based semiconductor device according to the exemplary embodiment of the present invention moves the current through the ohmic contact when being driven at lower voltage than the turn-on voltage of the schottky contact and moves the current through the schottky contact with the ohmic contact when being driven the higher voltage than the turn-on voltage of the schottky contact, such that it can be operated at the lower turn-on voltage, thereby making it possible to improve the switching operation efficiency and increase the forward current amount.

Further, the nitride based semiconductor device 100 according to the exemplary embodiment of the present invention includes the ohmic contact within the schottky contact, together with the schottky contact on the anode structure, thereby making it possible to lower the electric field concentrated on the schottky electrode unit 136 at the time of the reverse operation. In particular, the third side 136′ of the schottky electrode unit 136 and the second side 134′ of the second ohmic electrodes 134 forms the coplanar with each other, such that the electric field concentrated on the third side 136′ of the schottky electrode unit 136 may be dispersed by the second ohmic electrodes 134 at the time of the reverse operation. Therefore, the exemplary embodiment of the present invention can disperse the electric field concentrated on the schottky electrode unit at the time of the reverse operation by inserting the ohmic contact into the schottky electrode unit and allowing the ohmic contact opposite to the cathode structure and the sides of the schottky electrode unit to form the coplanar, thereby making it possible to increase the withstand voltage at the time of the reverse operation.

Hereinafter, modified examples of a method for manufacturing a nitride-based semiconductor device according to another exemplary embodiment of the present invention will be described in detail. In this configuration, the overlapped description of the nitride based semiconductor device 100 described with reference to FIGS. 1 and 3 may be omitted or simplified.

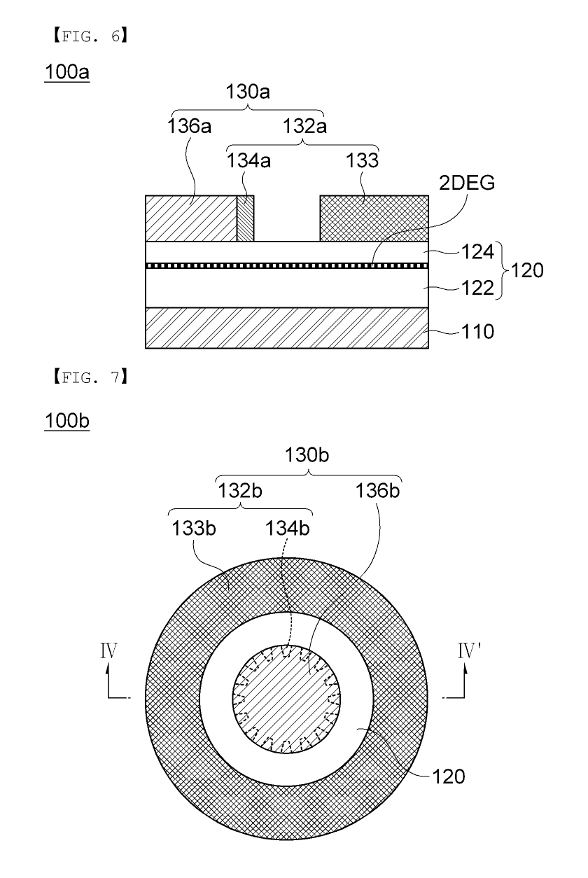

FIG. 5 is a plan view showing a modified example of a nitride based semiconductor device according to the exemplary embodiment of the present invention and FIG. 6 is a cross-sectional view taken along line III-III′ of FIG. 5.

Referring to FIGS. 5 and 6, a nitride based semiconductor device 100a according to a modified example of the present invention may include an electrode structure 130a having a structure different from the nitride based semiconductor device 100 with reference to FIG. 1.

In more detail, the nitride based semiconductor device 100a may be configured to include the base substrate 110, the semiconductor layer 120 disposed on the base substrate 110, and the cathode structure and the anode structure disposed on the semiconductor layer 120 to be spaced apart from each other. The cathode structure includes the first ohmic electrode 133 and the anode structure may include the third ohmic electrode 134a and a schottky electrode unit 136a. The first ohmic electrode 133 and the third ohmic electrode 134a may configure the ohmic electrode unit 132a.

In this case, the schottky electrode unit 136a may be disposed to be adjacent to the side of the third ohmic electrode 134a. That is, the schottky electrode unit 136a and the third ohmic electrode 134a are disposed laterally and the schottky electrode unit 136a and the third ohmic electrode 134a may be provided to have the substantially same thickness.

In this configuration, when the third ohmic electrode 134a is provided in plural, the third ohmic electrodes 134a are disposed in a line in a direction parallel with the side opposite to the first ohmic electrode 133 and the schottky electrode unit 136a may be provided to fill a space between the third ohmic electrodes 134a. Therefore, the side of the schottky electrode unit 136a opposite to the first ohmic electrode 133 has a rugged structure and the third ohmic electrodes 134a may have a structure in which it is laterally inserted into the concave portion of the rugged structure. In addition, the third ohmic electrodes 134a opposite to the cathode structure and the sides of the schottky electrode unit 136 may form the coplanar with each other.

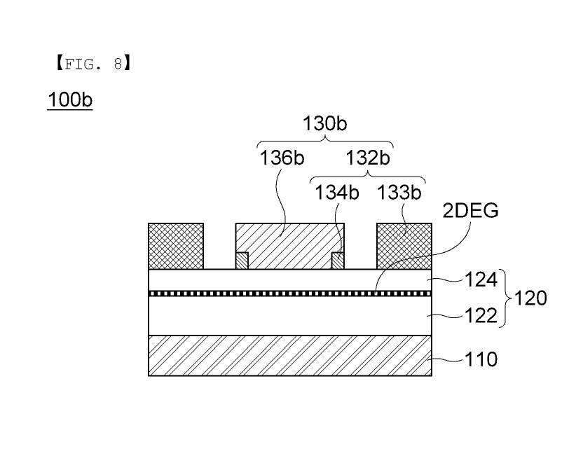

FIG. 7 is a plan view showing another modified example of a nitride based semiconductor device according to the exemplary embodiment of the present invention and FIG. 8 is a cross-sectional view taken along line IV-IV′ of FIG. 7.

Referring to FIGS. 7 and 8, a nitride based semiconductor device 100b according to another modified example of the present invention may include an electrode structure 130b having a circular or ring-shaped transverse section different from the nitride based semiconductor device 100 with reference to FIGS. 1 to 3.

In more detail, the nitride based semiconductor device 100b may be configured to include the base substrate 110, the semiconductor layer 120 disposed on the base substrate 110, and the cathode structure and the anode structure disposed on the semiconductor layer 120. The cathode structure includes a fourth ohmic electrode 133b and the anode structure may include a fifth ohmic electrode 134b and a schottky electrode unit 136b. The fourth ohmic electrode 133b and the fifth ohmic electrode 134b may configure the ohmic electrode unit 132b ohmic-contacting the epitaxial growth layer 120.

The schottky electrode unit 136b is disposed in the central area of the semiconductor layer 120 and the fourth ohmic electrode 133b is spaced apart from the schottky electrode unit 136b, such that it may be disposed to surround the schottky electrode 136b. Therefore, the fourth ohmic electrode 133c may have a ring shape. The fifth ohmic electrode 134b may be disposed to be opposite to the fourth ohmic electrode 133b in the edge area of the schottky electrode 136b. When the fifth ohmic electrode 134b is provided in plural, the plurality of fifth ohmic electrodes 134b may be disposed to be spaced by a predetermined interval along the edge area of the schottky electrode 136b. In addition, the fifth ohmic electrode 134b opposite to the cathode structure and the sides of the schottky electrode 136 may form the coplanar with each other.

The nitride based semiconductor device according to the exemplary embodiment of the present invention moves the current through the ohmic contact when being driven at lower voltage than the turn-on voltage of the schottky contact and moves the current through the schottky contact with the ohmic contact when being driven the higher voltage than the turn-on voltage of the schottky contact, such that it can be operated at the lower turn-on voltage, thereby making it possible to improve the switching operation efficiency and increase the forward current amount.

Further, the exemplary embodiment of the present invention can disperse the electric field concentrated on the schottky electrode unit at the time of the reverse operation by inserting the ohmic contact into the schottky electrode unit and allowing the ohmic contact opposite to the cathode structure and the sides of the schottky electrode unit to form the coplanar, thereby making it possible to increase the withstand voltage at the time of the reverse operation.

The above detail description is for illustrating the present invention. In addition, the above-described contents is only for showing and explaining preferred embodiment of the present invention, and the present invention may be used in a variety of other combinations, changes, and environments. In other words, modifications or corrections are possible within the scope of concepts of the invention set forth in the present embodiment, the scope of equivalents to written disclosures set forth in the present embodiment and/or the scope of techniques or knowledge in the art. The above-described embodiments are for explaining the best for implementing the present embodiment. Implementation to other forms known in the art and various modifications required in specific application fields and uses of the present invention are possible. Accordingly, the above detailed description of the present invention has no intent to limit the present invention by the presented embodiments. Also, the accompanying claims should be construed to include other embodiments.

What is claimed is:

1. A nitride based semiconductor device, comprising:
a base substrate;
a semiconductor layer disposed on the base substrate and generating 2-dimensional electron (2DEG) therein; and
an electrode structure disposed on the semiconductor layer,
wherein the electrode structure includes:
a first ohmic electrode ohmic-contacting the semiconductor layer;
a second ohmic electrode ohmic-contacting the semiconductor layer and spaced apart from the first ohmic electrode; and
a schottky electrode unit schottky-contacting the semiconductor layer and disposed to be adjacent to the second ohmic electrode while exposing the side of the second ohmic electrode opposite to the first ohmic electrode.

2. The nitride based semiconductor device according to claim 1, wherein the side of the second ohmic electrode opposite to the first ohmic electrode forms a coplanar with the side of the schottky electrode unit.

3. The nitride based semiconductor device according to claim 1, wherein the schottky electrode unit covers the second ohmic electrode to selectively expose only the side of the second ohmic electrode opposite to the first ohmic electrode.

4. The nitride based semiconductor device according to claim 1, wherein the second ohmic electrode is provided in plural, and
the second ohmic electrodes are disposed in a line along a direction parallel with the side of the first ohmic electrode opposite to the schottky electrode unit.

5. The nitride based semiconductor device according to claim 1, wherein the second ohmic electrode is provided in plural, and
each of the second ohmic electrodes has an island-shaped transverse section.

6. The nitride based semiconductor device according to claim 1, wherein the schottky electrode unit is formed so that the side thereof opposite to the first ohmic electrode has a rugged structure, and
the second ohmic electrode has a structure in which it is inserted into the concave portion of the rugged structure.

7. A nitride based semiconductor device, comprising:
a base substrate;
a semiconductor layer disposed on the base substrate; and
an electrode structure disposed on the semiconductor layer,
wherein the electrode structure includes:
a cathode structure ohmic-contacting the semiconductor layer; and
an anode structure having a schottky electrode schottky-contacting the semiconductor layer and an ohmic electrode ohmic-contacting the nitride layer,
wherein the schottky electrode is disposed to be adjacent to the ohmic electrode while exposing the side of the ohmic electrode opposite to the cathode structure.

8. The nitride based semiconductor device according to claim 7, wherein the ohmic electrode is to lower the turn-on voltage of the anode structure.

9. The nitride based semiconductor device according to claim 7, wherein the side of the schottky electrode opposite to the cathode structure forms a coplanar with the side of the ohmic electrode.

10. The nitride based semiconductor device according to claim 7, wherein the ohmic electrode is covered by the schottky electrode.

11. The nitride based semiconductor device according to claim 7, wherein the ohmic electrode is provided in plural, and
the ohmic electrodes are disposed in a line, being spaced by a predetermined interval according to the schottky electrode.

12. The nitride based semiconductor device according to claim 7, wherein the schottky electrode is disposed to be adjacent to the ohmic electrode at the side portion of the ohmic electrode.

13. The nitride based semiconductor device of claim 7, wherein the schottky electrode is disposed in the central area of the semiconductor layer,
the cathode structure is disposed to surround the schottky electrode, and
the ohmic electrodes are disposed to be spaced by a predetermined interval along the edge area of the schottky electrode.

14. The nitride based semiconductor device according to claim 7, wherein the schottky electrode is formed so that the side thereof opposite to the cathode structure has a rugged structure, and
the ohmic electrode has a structure in which it is inserted into the concave portion of the rugged structure.

15. The nitride based semiconductor device according to claim 7, wherein the base substrate is at least any one of a silicon substrate, a silicon carbide substrate, and a sapphire substrate.

16. The nitride based semiconductor device of claim 7, wherein the semiconductor layer includes:
a lower nitride layer using the base substrate as a seed layer and grown on the base substrate; and
an upper nitride layer formed on the lower nitride layer using the lower nitride layer as the seed layer and having a wider energy band gap than the lower nitride layer,
wherein 2-dimensional electron gas (2DEG) is generated between the lower nitride layer and the upper nitride layer.
